(19) United States
(12) Patent Application Publication
(10) Pub. No.: US 2024/0145489 A1
(43) Pub. Date: May 2, 2024

(54) DISPLAY DEVICE AND METHOD OF MANUFACTURING THE SAME

(71) Applicant: Samsung Display Co., LTD., Yongin-si (KR)

(72) Inventor: Ho Kyun AHN, Yongin-si (KR)

(73) Assignee: Samsung Display Co., LTD., Yongin-si (KR)

(21) Appl. No.: 18/495,975

(22) Filed: Oct. 27, 2023

(30) Foreign Application Priority Data
Oct. 31, 2022 (KR) 10-2022-0142939

(51) Int. Cl. H01L 27/12; H01L 21/66; H01L 25/16

(52) U.S. Cl. CPC H01L 27/124; H01L 22/12; H01L 25/167; H01L 27/1262

(57) ABSTRACT

A display device includes a first substrate including first and second surfaces facing each other, and including at least one opening penetrating the first and second surfaces; an inspection array disposed on the first surface and exposed on the second surface by the opening; a pixel circuit layer disposed on the first surface and including at least one transistor and an outer line; and a display element layer disposed on the pixel circuit layer and including a light emitting element electrically connected to the transistor. The inspection array is electrically connected to the outer line.

### CROSS-REFERENCE TO RELATED APPLICATION

This U.S. non-provisional patent application claims priority to and the benefit of Korean Patent Application No. 10-2022-0142939 under 35 U.S.C. § 119, filed Oct. 31, 2022, the contents of which are hereby incorporated by reference in its entirety.

### BACKGROUND

### 1. Technical Field

The disclosure relates to a display device and a method of manufacturing the same.

### 2. Description of the Related Art

Recently, as interest in information display is increasing, research and development on display devices are continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved manufacturing efficiency and a method of manufacturing the same.

In accordance with an aspect of the disclosure, a display device includes: a first substrate including first and second surfaces facing each other, and including at least one opening penetrating the first and second surfaces; an inspection array disposed on the first surface and exposed on the second surface by the opening; a pixel circuit layer disposed on the first surface and including at least one transistor and an outer line; and a display element layer disposed on the pixel circuit layer and including a light emitting element electrically connected to the transistor. The inspection array may be electrically connected to the outer line.

The outer line may be disposed on the inspection array with an insulating layer interposed between the outer line and the inspection array, and the outer line may be electrically connected to the inspection array through a contact hole penetrating the insulating layer.

The inspection array may include an inspection pad and an inspection line integral with the inspection pad. The inspection array may be disposed on the first surface at a position corresponding to the opening.

The outer line may extend on the insulating layer, and the outer line may be electrically connected to the inspection line through the contact hole.

The inspection pad may include a first inspection pad electrically connected to a first side of the inspection line, and a second inspection pad electrically connected to a second side of the inspection line. The inspection line may have a shape that bent at least once between the first inspection pad and the second inspection pad.

The outer line may not be connected to another line except for the inspection array.

The display device may further include a first pad disposed on the first surface and exposed on the second surface through a through hole penetrating the first surface and the second surface. The first pad may be electrically insulated from the inspection array.

The first pad and the inspection array may be disposed on a same layer.

The display device may further include a barrier layer disposed on the first substrate and covering the inspection array; a second substrate disposed between the barrier layer and the pixel circuit layer; and a thin film encapsulation layer disposed on the display element layer.

The display device may further include a second pad disposed in the through hole and electrically connected to the first pad; a flexible circuit film electrically connected to a lower surface of the second pad; and a driver disposed on the flexible circuit film and constructed and arranged to supply a signal to the first pad.

The display element layer may further include a light emitting element layer disposed on the pixel circuit layer and including the light emitting element; a color conversion layer disposed on the light emitting element layer and constructed and arranged to convert and output light emitted from the light emitting element; and a color filter layer disposed on the color conversion layer and constructed and arranged to selectively transmit the light converted by the color conversion layer.

The first substrate may include polyimide.

In accordance with another aspect of the disclosure, a method of manufacturing a display device includes: forming an inspection array on a first surface of a first substrate; forming a barrier layer covering the inspection array and forming a second substrate on the barrier layer; forming a pixel circuit layer including an outer line electrically connected to the inspection array and a dummy pad integral with the outer line on the second substrate; forming a display element layer including a light emitting element on the pixel circuit layer; forming a thin film encapsulation film on the display element layer; forming at least one opening penetrating the first surface and a second surface facing the first surface; and inspecting an electrical connection between the outer line and the inspection array by applying a selectable signal to the dummy pad.

The inspection array may include an inspection pad and an inspection line integral with the inspection pad. The inspection array may be formed on the first surface at a position corresponding to the opening.

The forming the pixel circuit layer may include forming at least one insulating layer on the second substrate; forming a contact hole sequentially penetrating the insulating layer, the second substrate, and the barrier layer and that exposes a portion of the inspection line; and forming the outer line electrically connected to the inspection line through the contact hole.

The dummy pad may include a first dummy pad electrically connected to a first side of the outer line and a second dummy pad spaced apart from the first dummy pad and electrically connected to a second side of the outer line. The inspecting of the electrical connection may comprise confirming a disconnection defect in the electrical connection of the inspection array based on applying the selectable signal to the first and second dummy pads.

The inspecting the electrical connection may include confirming whether the first substrate exists between a probe pin and the inspection pad based on contacting the probe pin to the inspection pad of the inspection array.

The forming the inspection array may include forming a first pad electrically insulated from the inspection array on the first surface.

The dummy pad may be removed from the first substrate after the inspecting the electrical connection.

The outer line may not be connected to other lines except for the inspection array.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a multi-screen display device according to an embodiment.

FIG. 2 is a schematic plan view illustrating a first display device of FIG. 1.

FIG. 3 is a schematic cross-sectional view illustrating the first display device of FIG. 2.

FIG. 4 is a schematic cross-sectional view illustrating a display panel of FIG. 3.

FIG. 5 is a schematic cross-sectional view illustrating the display panel of FIG. 4.

FIG. 6 is a schematic cross-sectional view taken along line I-I′ of FIG. 2.

FIG. 7 is a schematic bottom view illustrating a display device according to an embodiment.

FIG. 8 is a schematic perspective view illustrating the display device according to an embodiment.

FIG. 9 is a schematic bottom view illustrating the display device of FIG. 8.

FIG. 10 is a schematic enlarged view illustrating a portion EA of FIG. 8.

FIGS. 11 and 12 are schematic cross-sectional views taken along line II-II′ of FIG. 8.

FIG. 13 is a schematic perspective view illustrating a state in which a dummy area is removed from the display device of FIG. 8.

FIGS. 14A to 14F are schematic cross-sectional views illustrating a manufacturing sequence of a display device according to an embodiment, and are schematic cross-sectional views taken along line II-II′ of FIG. 8.

FIG. 15 is a schematic flowchart illustrating a method of manufacturing a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity Like numbers and/or reference characters refer to like elements throughout.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the obj ect from the top, and the phrase “in a schematic cross-sectional view” means viewing a cross-section of which the object is vertically cut from the side. Hence, the expression “in a plan view” used herein may mean that an object is viewed in the third direction DR3 from the top. The phrase “in a schematic cross-sectional view” means viewing a cross-section in the first direction DR1 or the second direction DR2 of which the object is vertically cut from the side.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “disposed on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

In case that an element is referred to as being “in contact” or “contacted” or the like to another element, the element may be in “electrical contact” or in “physical contact” with another element; or in “indirect contact” or in “direct contact” with another element.

A description that a component is “configured to” perform a specified operation may be defined as a case where the component is constructed and arranged with structural features that can cause the component to perform the specified operation.

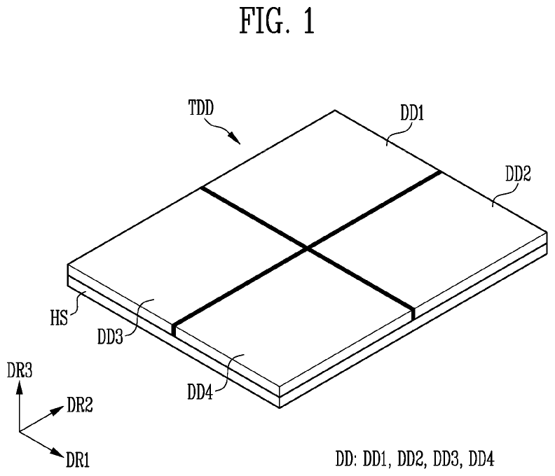

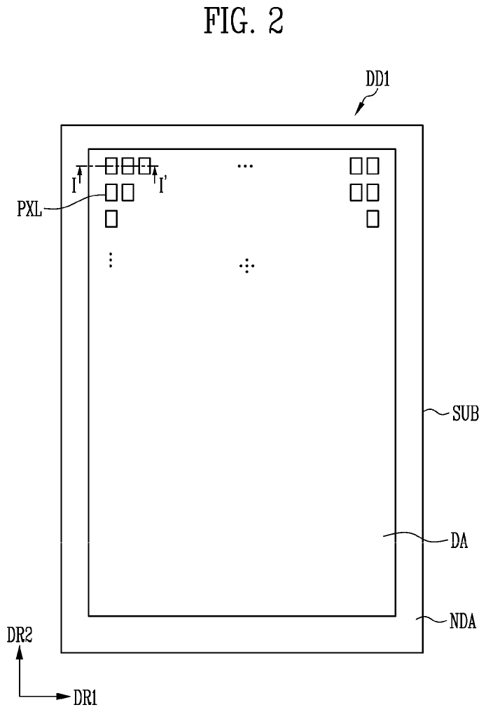

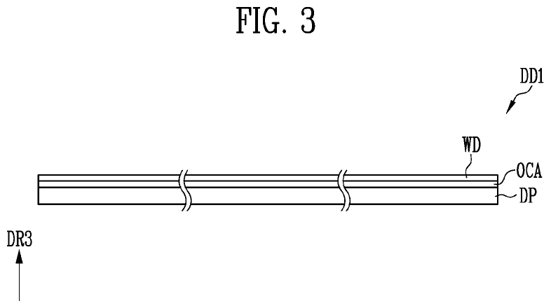

FIG. 1 is a schematic plan view illustrating a multi-screen display device TDD according to an embodiment. FIG. 2 is a schematic plan view illustrating a first display device DD1 of FIG. 1. FIG. 3 is a schematic cross-sectional view illustrating the first display device DD1 of FIG. 2.

Referring to FIGS. 1 to 3, the multi-screen display device TDD may include display devices DD. The multi-screen display device TDD (also referred to as a tiled display) may include display devices DD arranged in a matrix form along a first direction DR1 and a second direction DR2 and a housing HS.

The display devices DD may display images individually or may display divided images. The display devices DD may include, for example, a first display device DD1, a second display device DD2, a third display device DD3, a fourth display device DD4, or a combination thereof.

The first to fourth display devices DD1 to DD4 may be arranged side by side so that each display surface (or image display surface) on which an image is displayed faces one direction (for example, a third direction DR3). The first to fourth display devices DD1 to DD4 may have the same size (or area), but the disclosure is not limited thereto. According to an embodiment, each of the first to fourth display devices DD1 to DD4 may have a different size (or area) from adjacent display devices to meet design conditions of an applied multi-screen display device TDD.

Each of the first to fourth display devices DD1 to DD4 may have various shapes, and for example, may be in a rectangular plate shape having two pairs of sides parallel to each other, but the disclosure is limited thereto. In case that each of the first to fourth display devices DD1 to DD4 is in a rectangular plate shape, a first pair of sides among the two pairs of sides may be longer than a second pair of sides. For example, each of the first to fourth display devices DD1 to DD4 may have a rectangular shape having a pair of long sides and a pair of short sides. An extension direction of the long side is indicated as the second direction DR2, an extension direction of the short side is indicated as the first direction DR1, and a direction perpendicular to the extension direction of the long side and the short side is indicated as the third direction DR3. As described above, each of the first to fourth display devices DD1 to DD4 in a rectangular plate shape may have a shape in which a corner where a long side and a short side meet is rounded.

The first to fourth display devices DD1 to DD4 may be arranged in a matrix form. The matrix form may include at least one row and at least two columns.

The housing HS may physically couple the first to fourth display devices DD1 to DD4 so that the first to fourth display devices DD1 to DD4 constitute one multi-screen display device TDD. The housing HS may be disposed on one surface (or a lower surface) of the first to fourth display devices DD1 to DD4 to control and/or fix movements of the first to fourth display devices DD1 to DD4. Each of the first to fourth display devices DD1 to DD4 may be detachably coupled to the housing HS through at least one fastening member (not shown). Accordingly, since each of the first to fourth display devices DD1 to DD4 may be readily detached from and attached to the housing HS, in case that a defect occurs in one of the first to fourth display devices DD1 to DD4, it can be readily repaired by detaching the one display device.

The first to fourth display devices DD1 to DD4 may have substantially the same or similar structures. Therefore, the description of the first display device DD1 described with reference to FIGS. 2 and 3 will be applicable to the second to fourth display devices DD2 to DD4.

The first display device DD1 (or display device DD) may include a substrate SUB including a display area DA displaying an image and a non-display area NDA disposed on at least a first side of the display area DA. The non-display area NDA may be an area in which an image is not displayed.

The display area DA may include pixels PXL to display an image. Each of the pixels PXL may include an organic light emitting diode including an organic light emitting layer, a micro LED, a quantum dot light emitting element including a quantum dot light emitting layer, an inorganic light emitting element including an inorganic semiconductor, or a combination thereof. An embodiment in which each of pixels PXL includes an inorganic light emitting element will be described, but the disclosure is not limited thereto.

According to an embodiment, the first display device DD1 may include a sensing area and a non-sensing area. The first display device DD1 may not only display an image through the sensing area, but also may detect a touch input made on an image display surface (or input surface) or light incident from the front. The non-sensing area may surround the sensing area, but the disclosure is not limited thereto.

The first display device DD1 may include a display panel DP and a window WD.

The display panel DP may display an image. The display panel DP may be implemented based on a display panel capable of self-light emitting such as an organic light emitting display panel (OLED panel) using an organic light emitting diode as a light emitting element, a nano-scale LED display panel using an ultra-small light emitting diode as a light emitting element, and/or a quantum dot organic light emitting display panel (QD OLED panel) using quantum dots and organic light emitting diodes. The display panel DP also may be implemented based on a non-light emitting display panel such as a liquid crystal display panel (LCD panel), an electro-phoretic display panel (EPD panel), and/or an electro-wetting display panel (EWD panel). In case that a non-light emitting display panel is used as the display panel DP, the first display device DD1 may include a backlight unit for supplying light to the display panel DP.

The window WD for protecting an exposed surface of the display panel DP may be disposed on the display panel DP. The window WD may protect the display panel DP from external impact and provide an input surface and/or a display surface to a user. The window WD may be coupled to the display panel DP using an optically transparent adhesive member OCA.

The window WD may have a multi-layer structure selected from a glass substrate, a plastic film, and a plastic substrate. Such a multi-layer structure may be formed through a continuous process or a bonding process using an adhesive layer. The window WD may be wholly or partially flexible.

A touch sensor (not shown) may be disposed between the display panel DP and the window WD. The touch sensor may be directly disposed on a surface of the display panel DP on which an image is displayed to receive a user's touch input. The expression “directly disposed” may exclude attachment using a separate adhesive layer, and may mean formation by a continuous process.

Due to the non-display area NDA, for example, a seam area located in a boundary area between the first to fourth display devices DD1 to DD4, an image displayed on a screen of the multi-screen display device TDD may be disconnected. In case that the width (or area) of the seam area is relatively large, the disconnection of the image may be intensified in the boundary area between the first to fourth display devices DD1 to DD4.

In case that the width (or area) of the seam area is reduced, the size of the display area DA of a corresponding display device DD may be expanded without increasing the size of each of the first to fourth display devices DD1 to DD4. Accordingly, a larger display area DA may be manufactured based on the reduced seam area. In case that the seam area is reduced in the multi-screen display device TDD using the first to fourth display devices DD1 to DD4, visibility of the boundary between the first to fourth display devices DD1 to DD4 can be minimized, and a more natural screen can be constructed.

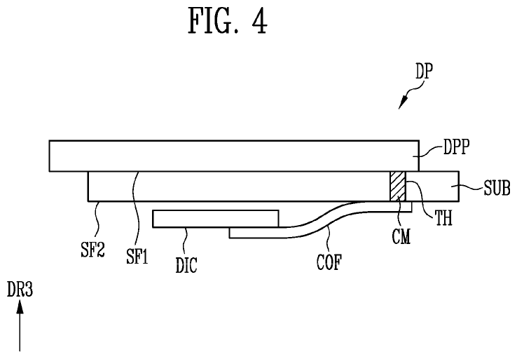

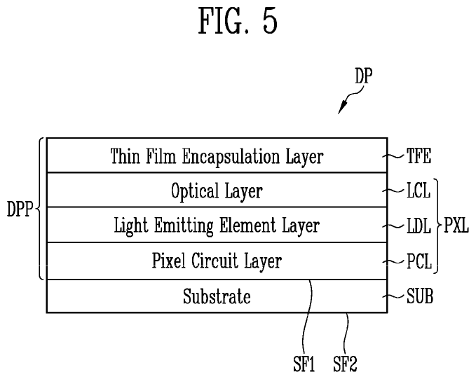

FIG. 4 is a schematic cross-sectional view illustrating a display panel DP of FIG. 3. FIG. 5 is a schematic cross-sectional view illustrating the display panel DP of FIG. 4.

In FIGS. 4 and 5, in order to avoid overlapping descriptions, differences from the above-described embodiments will be mainly described.

Referring to FIGS. 1 to 5, the display panel DP according to an embodiment may include the substrate SUB and a display part DPP.

The substrate SUB may include a first surface SF1 and a second surface SF2 facing each other in the third direction DR3 (also referred to herein as a thickness direction DR3).

The substrate SUB may be made of an insulating material such as glass or resin. The substrate SUB may be made of a material having flexibility to be bent or folded, and may have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, or a combination thereof. However, the material constituting the substrate SUB is not limited to the above-described embodiments. In an embodiment, the substrate SUB may include polyimide.

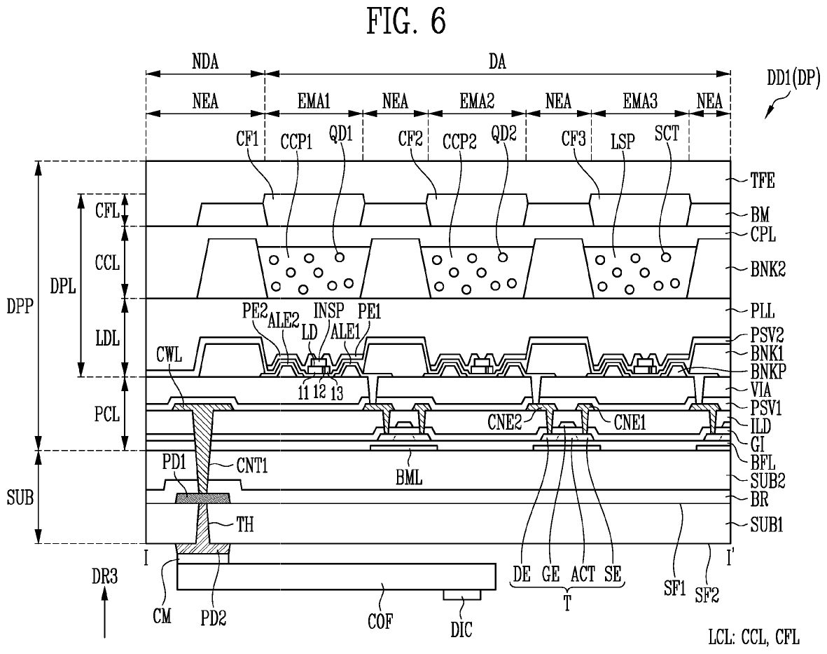

The display part DPP may include pixels PXL disposed on the first surface SF1 of the substrate SUB. The display part DPP of each pixel PXL may include a pixel circuit layer PCL, a light emitting element layer LDL, an optic al layer LCL, and a thin film encapsulation layer TFE. The light emitting element layer LDL and the optical layer LCL described above may constitute a display element layer DPL (refer to FIG. 6).

The pixel circuit layer PCL may be disposed on the substrate SUB. The pixel circuit layer PCL may include circuit elements including transistors and signal lines electrically connected to the circuit elements. For example, each transistor may have a form in which a semiconductor layer, a gate electrode, and source or drain electrodes are sequentially stacked each other with an insulating layer interposed therebetween. The semiconductor layer may include amorphous silicon, poly silicon, low temperature poly silicon, an organic semiconductor, or a combination thereof. The gate electrode and the source or drain electrodes may include of aluminum (Al), copper (Cu), titanium (Ti), molybdenum (Mo), or a combination thereof, but the disclosure is not limited thereto. Also, the pixel circuit layer PCL may include one or more insulating layers.

The light emitting element layer LDL of the display element layer DPL may be disposed on the pixel circuit layer PCL.

The light emitting element layer LDL may be disposed on the pixel circuit layer PCL. A light emitting element emitting light and electrodes electrically connected to the light emitting element may be positioned in the light emitting element layer LDL.

The optical layer LCL may be disposed on the light emitting element layer LDL. The optical layer LCL may improve light output efficiency of each pixel PXL by converting light emitted from the light emitting element into light having excellent color reproducibility. The optical layer LCL may include a color conversion layer and a color filter layer.

The thin film encapsulation layer TFE may be disposed on the optical layer LCL of the display element layer DPL.

The thin film encapsulation layer TFE may be an encapsulation substrate or may have a form of an encapsulation film made of a multi-layer film. In case that the thin film encapsulation layer TFE has the form of the encapsulation film, the thin film encapsulation layer TFE may include an inorganic film and/or an organic film. For example, the thin film encapsulation layer TFE may have a form in which an inorganic layer, an organic layer, and an inorganic layer are sequentially stacked each other. The thin film encapsulation layer TFE may reduce or prevent external air and moisture from penetrating into the display element layer DPL.

According to an embodiment, the display part DPP may optionally further include a flexible substrate disposed between the substrate SUB and the pixel circuit layer PCL.

In an embodiment, the substrate SUB may include at least one through hole TH penetrating at least one region of the substrate SUB. For example, the substrate SUB may include at least one through hole TH penetrating the first surface SF1 and the second surface SF2. A conductive member CM may be positioned inside the through hole TH. The conductive member CM may directly contact components disposed on the first and second surfaces SF1 and SF2 of the substrate SUB, and electrically and/or physically connect the component on the first surface SF1 and the component on the second surface SF2. For example, the conductive member CM may directly contact the display part DPP disposed on the first surface SF1 of the substrate SUB and a driver DIC disposed on the second surface SF2 of the substrate SUB, and electrically and/or physically connect the display part DPP and the driver DIC.

The driver DIC may be disposed on the second surface SF2 of the substrate SUB and electrically connected to the display part DPP through the conductive member CM described above. The driver DIC may be a printed circuit board that is constructed and arranged to generate and supply overall driving signals and power source signals necessary for driving the display panel DP and provide them to the display panel DP. In an embodiment, the driver DIC may be disposed on a flexible circuit film COF, and the driver DIC may be electrically connected to the conductive member CM through the flexible circuit film COF.

The flexible circuit film COF may electrically connect the conductive member CM and the driver DIC. The flexible circuit film COF may process various signals input from the driver DIC and output the processed signals to the display panel DP. A first end of the flexible circuit film COF may be electrically connected to the conductive member CM, and a second end facing the first end may be electrically connected to the driver DIC.

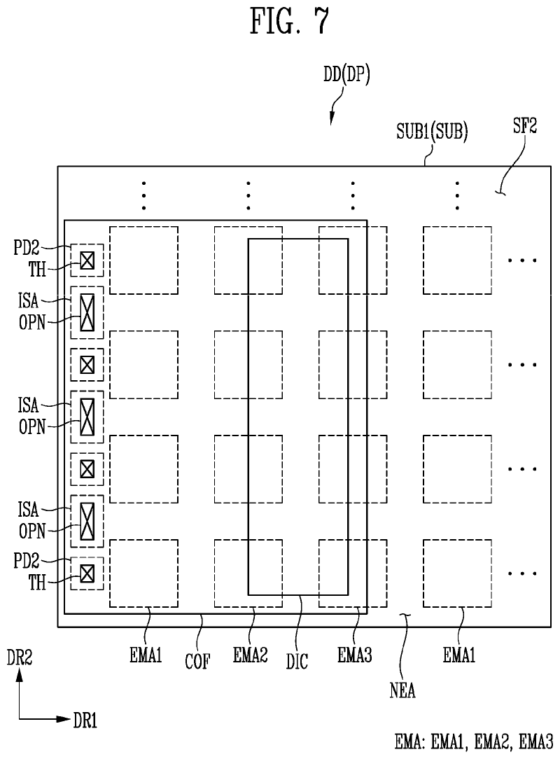

FIG. 6 is a schematic cross-sectional view taken along line I-I′ of FIG. 2. FIG. 7 is a schematic bottom view illustrating a display device DD according to an embodiment.

In FIG. 7, for convenience of description, the display panel DP in the display device DD is briefly shown centering on the second surface SF2 on which no image is displayed.

Referring to FIGS. 1 to 7, the display area DA of the display device DD (or display panel DP) may include pixels PXL. The pixels PXL may include an emission area EMA and a non-emission area NEA. In an embodiment, the emission area EMA may include first, second, and third emission areas EMA1, EMA2, and EMA3. Each of the first, second, and third emission areas EMA1, EMA2, and EMA3 may be an area from which light is emitted from a corresponding pixel PXL to outside. Each of the first, second, and third emission areas EMA1, EMA2, and EMA3 may be an area in which light is emitted from the first surface SF1 of the substrate SUB toward the upper direction thereof. For example, the first emission area EMA1 may be the emission area EMA of the pixel PXL (hereinafter referred to as a “first pixel”) that emits red light among the pixels PXL. The second emission area EMA2 may be the emission area EMA of the pixel PXL (hereinafter referred to as a “second pixel”) that emits green light among the pixels PXL. The third emission area EMA3 may be the emission area EMA of the pixel PXL (hereinafter referred to as a “third pixel”) that emits blue light among the pixels PXL. However, the disclosure is not limited thereto.

The display device DD may include the substrate SUB and the display part DPP.

The substrate SUB may include a first substrate SUB1, a barrier layer BR, and a second substrate SUB2.

The first substrate SUB1 may support the display device DD. The first substrate SUB1 may be a base substrate or a base member. The first substrate SUB1 may be a flexible substrate capable of being bent, folded, or rolled. For example, the first substrate SUB1 may include an insulating material such as a polymer resin such as polyimide, but the disclosure is not limited thereto. According to an embodiment, the first substrate SUB1 may include a glass material or a metal material. The first substrate SUB1 may include the first surface SF1 and the second surface SF2 facing each other along the thickness direction (or the third direction DR3). The first surface SF1 may be an upper surface, and the second surface SF2 may be a rear surface (or a lower surface).

The first substrate SUB1 may be partially opened to include through holes TH penetrating the first and second surfaces SF1 and SF2. The through holes TH may be disposed in the non-display area NDA and/or the display area DA. A second pad PD2 may be disposed on the second surface SF2 of the first substrate SUB1. For example, the second pad PD2 may be disposed in a corresponding through hole TH and electrically connected to a component disposed on the first surface SF1 of the first substrate SUB1, for example, a first pad PD1.

The first substrate SUB1 may be partially opened to include openings OPN penetrating the first and second surfaces SF1 and SF2. The openings OPN may be disposed in the non-display area NDA and/or the display area DA. For convenience of description, the through holes TH and the openings OPN are shown to be spaced apart from each other, but the disclosure is not limited thereto. The through holes TH may be partial areas of the openings OPN.

The first pad PD1 may be disposed on the first surface SF1 of the first substrate SUB1. The first pad PD1 may be electrically connected to the second pad PD2 disposed in the through hole TH. According to an embodiment, a dummy barrier layer may be disposed to enhance adhesion between the first pad PD1 and the first substrate SUB1.

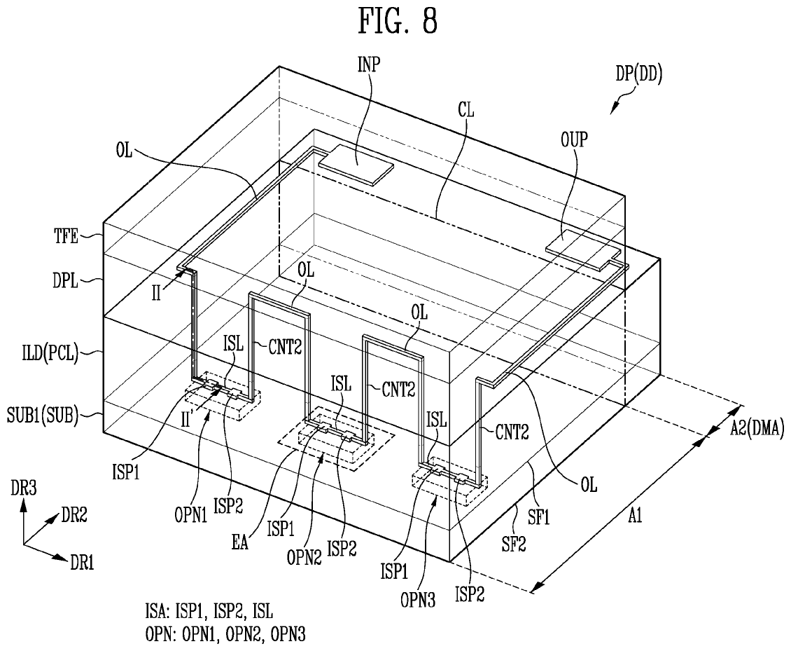

An inspection array ISA may be disposed on the first surface SF1 of the first substrate SUB1. The inspection array ISA may be partially exposed on the second surface SF2 of the first substrate SUB1 by an opening OPN. The inspection array ISA may be a component that can be used to determine an etching degree of the first substrate SUB1 in the process of forming the openings OPN. A detailed description of the inspection array ISA will be described later with reference to FIGS. 8 to 13.

The barrier layer BR may be disposed on the first surface SF1 of the first substrate SUB1. The barrier layer BR may cover the first pad PD1 to protect the first pad PD1. The barrier layer BR may include an inorganic insulating layer including an inorganic material capable of preventing penetration of air or moisture. For example, the barrier layer BR may include at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a combination thereof.

The second substrate SUB2 may be disposed on the barrier layer BR. The second substrate SUB2 may be a base substrate or a base member, and may be made of an insulating material such as a polymer resin. The second substrate SUB2 may be a flexible substrate capable of being bent, folded, or rolled. For example, the second substrate SUB2 may include polyimide, but the disclosure is not limited thereto.

The barrier layer BR and the second substrate SUB2 may include a first contact hole CNT1 disposed in the non-display area NDA. For example, the barrier layer BR and the second substrate SUB2 may be partially opened to include the first contact hole CNT1 exposing the first pad PD1 by removing a portion thereof during a manufacturing process. According to an embodiment, the first contact hole CNT 1 may be located in the display area DA.

The pixel circuit layer PCL may be disposed or formed on the second substrate SUB2.

The pixel circuit layer PCL may include the circuit elements (for example, a transistor T) and the signal lines electrically connected to the circuit elements. Also, the pixel circuit layer PCL may include at least one insulating layer. For example, the pixel circuit layer PCL may include a buffer layer BFL, a gate insulating layer GI, an interlayer insulating layer ILD, a first passivation layer PSV1, and a via layer VIA sequentially stacked each other on the second substrate SUB2.

The buffer layer BFL may be disposed on an entire surface of the second substrate SUB2. The buffer layer BFL may prevent impurities from diffusing into the transistor T. The buffer layer BFL may be an inorganic insulating layer including an inorganic material. The buffer layer BFL may include at least one of silicon nitride (SiNx), silicon oxide (SiOx), and silicon oxynitride (SiOxNy), at least one of metal oxides such as aluminum oxide (AlOx), or a combination thereof. The buffer layer BFL may be a single layer structure, but may also be a multi-layer structure including a double layer. In case that the buffer layer BFL is a multi-layer structure, each layer may be formed of a same material or different materials. The buffer layer BFL may be omitted depending on the material of the second substrate SUB2 and process conditions.

The gate insulating layer GI may be disposed on an entire surface of the buffer layer BFL. The gate insulating layer GI may include a same material as the buffer layer BFL described above or may include a suitable material selected from materials constituting the buffer layer BFL. For example, the gate insulating layer GI may be an inorganic insulating layer including an inorganic material.

The interlayer insulating layer ILD may be disposed and/or formed on an entire surface of the gate insulating layer GI. The interlayer insulating layer ILD may include a same material as the buffer layer BFL or may include one or more suitable materials selected from materials constituting the buffer layer BFL. For example, the interlayer insulating layer ILD may be an inorganic insulating layer including an inorganic material.

In an embodiment, each of the interlayer insulating layer ILD, the gate insulating layer GI, and the buffer layer BFL may be partially opened to include the first contact hole CNT1.

The first passivation layer PSV1 may be disposed and/or formed on an entire surface of the interlayer insulating layer ILD. The first passivation layer PSV1 may include a same material as the buffer layer BFL or may include one or more suitable materials selected from materials constituting the buffer layer BFL. For example, the buffer layer BFL may be an inorganic insulating layer including an inorganic material.

The via layer VIA may be disposed and/or formed on an entire surface of the first passivation layer PSV1. The via layer VIA may be an inorganic insulating layer including an inorganic material or an organic insulating layer including an organic material. The inorganic insulating layer may include, for example, silicon oxide (SiOₓ), silicon nitride (SiNₓ), silicon oxynitride (SiOₓN_{y}), aluminum oxide (AlOₓ), or a combination thereof. The organic insulating layer may include, for example, at least one of an acrylic resin (polyacrylates resin), an epoxy resin, a phenolic resin, a polyamides resin, a polyimides rein, an unsaturated polyesters resin, a poly-phenylen ethers resin, a poly-phenylene sulfides resin, a benzocyclobutene resin, or a combination thereof.

The transistor T may be disposed and/or formed on the buffer layer BFL. The transistor T may include a driving transistor constructed and arranged to drive a driving current of the light emitting element LD.

The transistor T may include a semiconductor pattern and a gate electrode GE overlapping and facing at least a portion of the semiconductor pattern in the thickness direction DR3. The semiconductor pattern may include a channel region ACT, a first contact region SE, and a second contact region DE. The first contact region SE may be a source region, and the second contact region DE may be a drain region.

The gate electrode GE may be disposed and/or formed on the gate insulating layer GI to correspond to the channel region ACT. For example, the gate electrode GE may be positioned between the gate insulating layer GI and the interlayer insulating layer ILD. The gate electrode GE may be disposed on the gate insulating layer GI to overlap and face the channel region ACT in the thickness direction DR3.

The semiconductor pattern may be disposed and/or formed on the buffer layer BFL. The channel region ACT, the first contact region SE, and the second contact region DE may be the semiconductor pattern made of poly silicon, amorphous silicon, or an oxide semiconductor. The channel region ACT, the first contact region SE, and the second contact region DE may be formed of a semiconductor layer undoped or doped with impurities. For example, the first contact region SE and the second contact region DE may be formed of a semiconductor layer doped with impurities, and the channel region ACT may be formed of a semiconductor layer not doped with impurities.

The channel region ACT may overlap and face the gate electrode GE of the transistor T in the thickness direction DR3.

The first contact region SE may electrically contact a first end of the channel region ACT, and may be electrically connected to a first connection member CNE1 through a contact hole penetrating the interlayer insulating layer ILD and the gate insulating layer GI.

The first connection member CNE1 may be disposed and/or formed on the interlayer insulating layer ILD.

The second contact region DE may electrically contact a second end of the channel region ACT, and may be electrically connected to a second connection member CNE2 through a contact hole penetrating the interlayer insulating layer ILD and the gate insulating layer GI.

The second connection member CNE2 may be disposed and/or formed on the interlayer insulating layer ILD. The second connection member CNE2 may be electrically connected to the second contact region DE, and may be electrically connected to a component of the light emitting element layer LDL, for example, a first alignment electrode ALE1, through a contact hole penetrating the first passivation layer PSV1 and the via layer VIA.

A lower metal pattern BML may be disposed below the transistor T described above. The lower metal pattern BML may be a conductive layer positioned between the second substrate SUB2 and the buffer layer BFL. The lower metal pattern BML may be electrically connected to the transistor T. Hence, the driving range of a voltage supplied to the gate electrode GE of the transistor T may be widened. The lower metal pattern BML may be electrically connected to the first contact region SE of the transistor T to stabilize the channel region ACT of the transistor T. The lower metal pattern BML electrically connected to the transistor T may prevent floating of the lower metal pattern BML.

The lower metal pattern BML may be composed of a single layer including one or a mixture selected from the group consisting of copper (Cu), molybdenum (Mo), tungsten (W), aluminum neodymium (AlNd), titanium (Ti), aluminum (Al), silver (Ag), and alloys thereof. The lower metal pattern BML may be formed of a double-layer or multi-layer structure made of a low-resistance material such as molybdenum (Mo), titanium (Ti), copper (Cu), aluminum (Al) or silver (Ag) to reduce line resistance. The lower metal pattern BML may overlap and face the semiconductor pattern in the thickness direction DR3. The lower metal pattern BML may be used as a light blocking member that protects the transistor T by blocking light that may be introduced from a rear surface of the substrate SUB. The lower metal pattern BML may be made of a light blocking and/or light absorbing material. For example, the lower metal pattern BML may include an opaque metal layer.

The first passivation layer PSV1 and the via layer VIA may be sequentially disposed on the transistor T having the above configuration.

The pixel circuit layer PCL may further include a connection line CWL disposed on the interlayer insulating layer ILD.

The connection line CWL may be electrically connected to the first pad PD1 through the first contact hole CNT1. The connection line CWL may be disposed to be spaced apart from the first and second connection members CNE1 and CNE2 on the interlayer insulating layer ILD. According to an embodiment, the connection line CWL may be disposed and/or formed on the buffer layer BFL or may be disposed and/or formed on the gate insulating layer GI. In an embodiment, the connection line CWL may supply an electrical signal received from the first pad PD1 to the transistor T or signal lines electrically connected to the transistor T, for example, a data line, a scan line, and power source lines.

The display element layer DPL may be disposed and/or formed on the pixel circuit layer PCL (or the via layer VIA). The display element layer DPL may include the light emitting element layer LDL and the optical layer LCL. The optical layer LCL (shown in FIG. 5) may include a color conversion layer CCL and a color filter layer CFL (shown in FIG. 6).

The light emitting element layer LDL may include a bank pattern BNKP, first and second alignment electrodes ALE1 and ALE2, a light emitting element LD, a first bank BNK1, first and second electrodes PE1 and PE2.

The bank pattern BNKP may be disposed on the via layer VIA. The bank pattern BNKP may protrude in the third direction DR3 on one surface of the via layer VIA. The bank pattern BNKP may include an inorganic insulating layer including an inorganic material or an organic insulating layer including an organic material. According to an embodiment, the bank pattern BNKP may include a single inorganic insulating layer and/or a single organic insulating layer, but the disclosure is not limited thereto. According to an embodiment, the bank pattern BNKP may be omitted.

Each of the first and second alignment electrodes ALE1 and ALE2 may be disposed on the via layer VIA and the bank pattern BNKP. The first alignment electrode ALE1 may be disposed on the bank pattern BNKP disposed on a first side of the light emitting element LD, and the second alignment electrode ALE2 may be disposed on the bank pattern BNKP disposed on a second side of the light emitting element LD. The first and second alignment electrodes ALE1 and ALE2 may be used as alignment lines for aligning the light emitting element LD based on receiving an alignment signal before the light emitting element LD is aligned in the first, second, and third emission areas EMA1, EMA2, and EMA3, respectively.

The first alignment electrode ALE1 may be electrically connected to the second connection member CNE2 through a contact hole penetrating the via layer VIA and the first passivation layer PSV1. The first alignment electrode ALE1 may be electrically connected to the first electrode PE1 and electrically connected to a second semiconductor layer 13 (or p-type semiconductor) positioned at a first end of the light emitting element LD through the first electrode PE1. For example, the first alignment electrode ALE1 may receive a voltage proportional to the luminance of the light emitting element LD from a pixel circuit of the pixel PXL, but the disclosure is not limited thereto.

The second alignment electrode ALE2 may be electrically connected to the second electrode PE2 and electrically connected to a first semiconductor layer 11 (or n-type semiconductor) positioned at a second end of the light emitting element LD through the second electrode PE2. In an embodiment, the second alignment electrode ALE2 may be electrically connected to a selectable power source line disposed in the pixel circuit layer PCL, for example, a power source line to which a voltage of a low potential power source is supplied.

The first and second alignment electrodes ALE1 and ALE2 may be made of a material having a reflectivity so that light emitted from the light emitting element LD may propagate in an image display direction (or a front direction) of the display device DD. For example, the first and second alignment electrodes ALE1 and ALE2 may be made of a conductive material. The conductive material may include an opaque metal so that light emitted from the light emitting element LD is reflected in the image display direction of the display device DD. The opaque metal may include, for example, a metal such as silver (Ag), magnesium (Mg), aluminum (Al), platinum (Pt), palladium (Pd), gold (Au), nickel (Ni), neodymium (Nd), iridium(Ir), chromium (Cr), titanium (Ti), an alloy thereof, or a combination thereof. However, materials of the first and second alignment electrodes ALE1 and ALE2 are not limited to the above-described embodiment. According to an embodiment, the first and second alignment electrodes ALE1 and ALE2 may include a transparent conductive material. The transparent conductive material may include a conductive oxide such as indium tin oxide (ITO), indium zinc oxide (IZO), zinc oxide (ZnOₓ), indium gallium zinc oxide (IGZO), or indium tin zinc oxide (ITZO), or may include a conductive polymer such as poly(3,4-ethylenedioxythiophene) (PEDOT), or a combination thereof.

Each of the first and second alignment electrodes ALE1 and ALE2 disposed on a corresponding bank pattern BNKP may be used as a reflective member together with the bank pattern BNKP. For example, the bank pattern BNKP, together with the first and second alignment electrodes ALE1 and ALE2 disposed thereon, may be used as a reflective member that improves the light output efficiency of the pixel PXL by guiding light emitted from each light emitting element LD to the image display direction of the display device DD.

The first bank BNK1 may be disposed in the non-emission area NEA of the via layer VIA. The first bank BNK1 may be formed between adjacent pixels PXL so as to surround the emission area EMA of each pixel PXL to form a pixel defining layer that partitions (or defines) the emission area EMA of a corresponding pixel PXL. In the step of supplying the light emitting elements LD to the emission area EMA, the first bank BNK1 may be a dam structure that prevents a solution (or ink) in which the light emitting elements LD are mixed from flowing into the emission area EMA of adjacent pixels PXL or uniformly controls the amount of solution supplied to each emission area EMA.

The first bank BNK1 and the bank pattern BNKP may be formed in a continuous process and disposed on a same or different layers, but the disclosure is not limited thereto. According to an embodiment, the first bank BNK1 and the bank pattern BNKP may be formed in the same process and may be disposed on a same layer.

A second passivation layer PSV2 may be disposed on the first bank BNK1, the first and second alignment electrodes ALE1 and ALE2, and the via layer VIA.

The second passivation layer PSV2 may be formed of an inorganic insulating layer made of an inorganic material. The second passivation layer PSV2 may be composed of a single layer or multiple layers. In case that the second passivation layer PSV2 is multiple layers, the second passivation layer PSV2 may be a distributed Bragg reflector (DBR) structure in which first and second inorganic layers having different refractive indices are alternately stacked each other.

The second passivation layer PSV2 may be entirely disposed over the emission area EMA and non-emission area NEA of each pixel PXL, but the disclosure is not limited thereto. According to an embodiment, the second passivation layer PSV2 may be located only in a specific area of each pixel PXL, for example, the emission area EMA.

The light emitting element LD may be disposed on the second passivation layer PSV2 in the emission area EMA. A plurality of light emitting elements LD may be disposed in the emission area EMA. For example, light emitting elements LD may be supplied (or inputted) to the emission area EMA through an inkjet printing method or the like, and the light emitting elements LD may be aligned between the first and second alignment electrodes ALE1 and ALE2 by an electric field formed by an alignment signal applied to the first and second alignment electrodes ALE1 and ALE2. For example, the light emitting elements LD may be aligned between the first alignment electrode ALE1 and the second alignment electrode ALE2 on the second passivation layer PSV2.

Viewed in a schematic cross-sectional view, the light emitting element LD may include a first end and a second end located at both ends (or facing each other) in a longitudinal direction. The second semiconductor layer 13 including a p-type semiconductor layer may be positioned at a first end, and the first semiconductor layer 11 including an n-type semiconductor layer may be positioned at a second end. An active layer 12 may be positioned between the first semiconductor layer 11 and the second semiconductor layer 13. The light emitting elements LD may be electrically connected in parallel to each other between the first alignment electrode ALE1 and the second alignment electrode ALE2.

The light emitting element LD may have a micrometer or nanometer size and may be an inorganic light emitting diode including an inorganic material. The inorganic light emitting diode may be aligned between the first and second alignment electrodes ALE1 and ALE2 by an electric field formed in a specific direction between the first and second alignment electrodes ALE1 and ALE2 facing each other.

The light emitting elements LD may include active layers made of a same material, and may emit light of the same wavelength range or light of the same color. Light emitted from each of the first to third emission areas EMA1, EMA2, and EMA3 of the light emitting element layer LDL may have the same color. For example, the light emitting elements LD may emit third color light or blue light having a peak wavelength in the range of about 440 nm to about 480 nm, the disclosure but is not limited thereto.

An insulation pattern INSP may be disposed on each of the light emitting elements LD. The insulating pattern INSP may be positioned on the light emitting element LD, and may partially cover an outer circumferential surface (or surface) of the light emitting element LD to expose a first end and a second end of the light emitting element LD to outside.

The insulating pattern INSP may include an inorganic insulating layer including an inorganic material or an organic insulating layer including an organic material. For example, the insulating pattern INSP may include an inorganic insulating layer suitable for protecting the active layer 12 of the light emitting element LD from external oxygen and moisture. However, the disclosure is not limited thereto, and the insulating pattern INSP may be formed of an organic insulating layer including an organic material depending on design conditions of the display device DD (or the display panel DP) to which the light emitting element LD is applied. The insulating pattern INSP may be composed of a single layer or multiple layers.

In case that a gap exists between the light emitting element LD and the second passivation layer PSV2 before the insulating pattern INSP is formed, the gap may be filled with the insulating pattern INSP in the process of forming the insulating pattern INSP.

Since the insulating pattern INSP is formed on the light emitting elements LD aligned in the emission area EMA of each pixel PXL, it is possible to prevent the light emitting elements LD from separating from the aligned position.

The first electrode PE1 may be disposed on the insulating pattern INSP, on a first end of the light emitting element LD, and on the second passivation layer PSV2. The first electrode PE1 may be electrically connected to the first alignment electrode ALE1 through a contact hole disposed in the second passivation layer PSV2. The first electrode PE1 may electrically contact a first end of the light emitting element LD and may be electrically connected to the second semiconductor layer 13 positioned at a first end of the light emitting element LD.

The second electrode PE2 may be disposed on the insulating pattern INSP, on a second end of the light emitting element LD, and on the second passivation layer PSV2. The second electrode PE2 may be electrically connected to the second alignment electrode ALE2 through a contact hole disposed in the second passivation layer PSV2. The second electrode PE2 may electrically contact a second end of the light emitting element LD and may be electrically connected to the first semiconductor layer 11 positioned at the second end of the light emitting element LD.

The first electrode PE1 may be electrically connected to the first alignment electrode ALE1, and the second electrode PE2 may be electrically connected to the second alignment electrode ALE2.

Each of the first and second electrodes PE1 and PE2 may be made of various transparent conductive materials. For example, each of the first and second electrodes PE1 and PE2 may include at least one of various transparent conductive materials such as indium tin oxide, indium zinc oxide, indium tin zinc oxide, aluminum zinc oxide, gallium zinc oxide, zinc tin oxide, or gallium tin oxide, or a combination thereof, and may be implemented as substantially transparent or translucent to satisfy a selectable light transmittance.

In an embodiment, the first electrode PE1 and the second electrode PE2 may be formed of the same or different layers. For example, the mutual position and/or formation order of the first electrode PE1 and the second electrode PE2 may be variously changed according to embodiments.

An overcoat layer PLL may be disposed on the first and second electrodes PE1 and PE2. The overcoat layer PLL may be used as a planarization layer that alleviates a step difference caused by components located thereunder. The overcoat layer PLL may be an organic insulating layer including an organic material, but the disclosure is not limited thereto.

The color conversion layer CCL may be disposed on the light emitting element layer LDL described above. The color conversion layer CCL may be constructed and arranged to cause converting and outputting of light emitted from the light emitting element LD. The color conversion layer CCL may include first and second color conversion patterns CCP1 and CCP2, a second bank BNK2, a light scattering pattern LSP, and a capping layer CPL.

The first color conversion pattern CCP1 may include first color conversion particles QD1. For example, the first color conversion particles QD1 may be red quantum dots. The first color conversion pattern CCP1 may include first color conversion particles QD1 dispersed in a selected matrix material such as a base resin. The first color conversion pattern CCP1 may be positioned to correspond to the first emission area EMA1 in the color conversion layer CCL.

The second color conversion pattern CCP2 may include second color conversion particles QD2. For example, the second color conversion particles QD2 may be green quantum dots. The second color conversion pattern CCP2 may include second color conversion particles QD2 dispersed in a selected matrix material such as a base resin. The second color conversion pattern CCP2 may be positioned to correspond to the second emission area EMA2 in the color conversion layer CCL.

The light scattering pattern LSP may include light scattering particles SCT. For example, the light scattering pattern LSP may include light scattering particles SCT dispersed in a selected matrix material such as a base resin. The light scattering pattern LSP may include light scattering particles SCT such as silica, but materials constituting the light scattering particles SCT are not limited thereto. According to an embodiment, the light scattering particles SCT may be omitted to provide the light scattering pattern LSP made of a transparent polymer. The light scattering pattern LSP may be positioned to correspond to the third emission area EMA3 in the color conversion layer CCL.

The second bank BNK2 may be located in the non-emission area NEA within the color conversion layer CCL. The second bank BNK2 may overlap and face the first bank BNK1 in the third direction DR3 (or thickness direction). The second bank BNK2 may block transmission of light. The second bank BNK2 may improve color reproducibility of the display device DD by preventing color mixing due to penetration of light between the first, second, and third emission areas EMA1, EMA2, and EMA3. The second bank BNK2 may be arranged in a lattice form surrounding each of the first, second, and third emission areas EMA1, EMA2, and EMA3.

The capping layer CPL may be disposed on the first and second color conversion patterns CCP1 and CCP2, the second bank BNK2, and the light scattering pattern LSP.

The capping layer CPL may be disposed on an entire surface of the display area DA where the pixel PXL is disposed to cover the first and second color conversion patterns CCP1 and CCP2, the second bank BNK2, and the light scattering pattern LSP, but the disclosure is not limited thereto. The capping layer CPL may be an inorganic insulating layer including an inorganic material. The capping layer CPL may include at least one of silicon nitride (SiNₓ), silicon oxide (SiOₓ), silicon oxynitride (SiOₓN_{y}), and aluminum oxide (AlOₓ), or a combination thereof. The capping layer CPL may entirely cover components located thereunder to block moisture or oxygen from entering the components from the outside.

The color filter layer CFL may be disposed and/or formed on the capping layer CPL. The color filter layer CFL may be constructed and arranged to selectively transmit the light converted by the color conversion layer CCL. The color filter layer CFL may include first, second, and third color filters CF1, CF2, and CF3 and a light blocking pattern BM.

The first color filter CF1 may be disposed on one surface of the capping layer CPL to correspond to the first color conversion pattern CCP1. The first color filter CF1 may be a red color filter. The first color filter CF1 may selectively transmit light of a first color (for example, red light), and may block or absorb light of a second color (for example, green light) and light of a third color (for example, red light).

The second color filter CF2 may be disposed on one surface of the capping layer CPL to correspond to the second color conversion pattern CCP2. The second color filter CF2 may be a green color filter. The second color filter CF2 may selectively transmit light of the second color and may block or absorb light of the first color and light of the third color.

The third color filter CF3 may be disposed on one surface of the capping layer CPL to correspond to the light scattering pattern LSP. The third color filter CF3 may be a blue color filter. The third color filter CF3 may selectively transmit light of the third color and may block or absorb light of the first color and light of the second color.

The light blocking pattern BM may be disposed on one surface of the capping layer CPL to correspond to the second bank BNK2. The light blocking pattern BM may block transmission of light. The light blocking pattern BM may block color mixing due to penetration of light between the first, second, and third emission areas EMA1, EMA2, and EMA3. The light blocking pattern BM may be disposed in a lattice form surrounding each of the first, second, and third emission areas EMA1, EMA2, and EMA3.

The light blocking pattern BM may be a multi-layer structure in which at least two or more color filters that selectively transmit light of different colors among the first, second, and third color filters CF1, CF2, and CF3 overlap and face each other in the thickness direction DR3. For example, the light blocking pattern BM may be a structure in which the first color filter CF1, the second color filter CF2, and the third color filter CF3 are sequentially stacked each other in the non-emission area NEA.

The thin film encapsulation layer TFE may be disposed and/or formed on the light blocking pattern BM and the first, second, and third color filters CF1, CF2, and CF3. The thin film encapsulation layer TFE may cover upper and side surfaces of the display element layer DPL. The thin film encapsulation layer TFE may include, for example, at least one inorganic layer to prevent penetration of oxygen or moisture. The thin film encapsulation layer TFE may include at least one organic layer to protect the display device DD from foreign substances.

The second pad PD2 may be disposed on the second surface SF2 of the first substrate SUB1. The second pad PD2 may be disposed in the through hole TH and electrically connected to the first pad PD1. The second pad PD2 may receive various voltages or signals from the flexible circuit film COF, and may supply a corresponding voltage or signal to the first pad PD1 and the connection line CWL. The flexible circuit film COF may be electrically connected to the second pad PD2 through the conductive member CM.

The flexible circuit film COF may be attached to a lower surface of the second pad PD2 by the conductive member CM. A first surface of the conductive member CM may be attached to the second pad PD2 and a second surface of the conductive member CM may be attached to the flexible circuit film COF. For example, the conductive member CM may include an anisotropic conductive film. In case that the conductive member CM includes the anisotropic conductive film, the conductive member CM may have conductivity in a region where the second pad PD2 and a contact pad of the flexible circuit film COF contact each other, and may electrically connect the flexible circuit film COF to the second pad PD2.

The flexible circuit film COF may be disposed on a lower portion (or the second surface SF2) of the first substrate SUB1. A first side of the flexible circuit film COF may be electrically connected to the second pad PD2 and a second side of the flexible circuit film COF may be electrically connected to a printed circuit board under the first substrate SUB1. The flexible circuit film COF may transmit a signal of the driver DIC to the display device DD. For example, the driver DIC may be an integrated circuit (IC).

The driver DIC may be constructed and arranged to convert digital video data into an analog data voltage based on a data control signal of the timing controller, and supply the converted data voltage to a data line of the display area DA through the flexible circuit film COF. The display device DD may include the first pad PD1 disposed on the barrier layer BR, the second pad PD2 disposed on the lower portion (or the second surface SF2) of the first substrate SUB1, and the flexible circuit film COF electrically connected to a lower surface of the second pad PD2, hence an area of the non-display area NDA can be minimized.

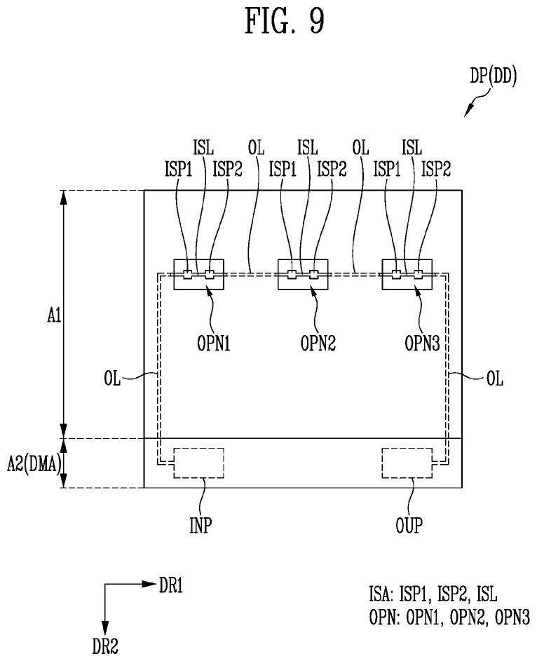

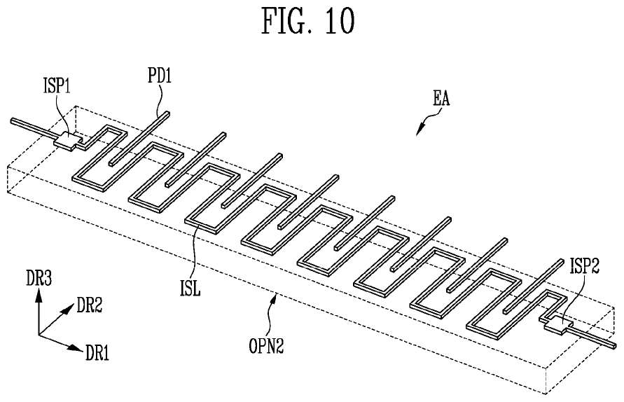

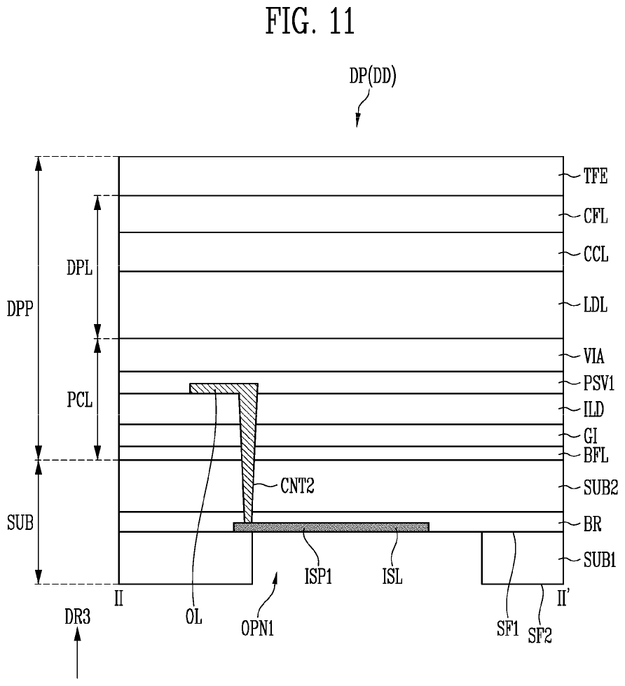

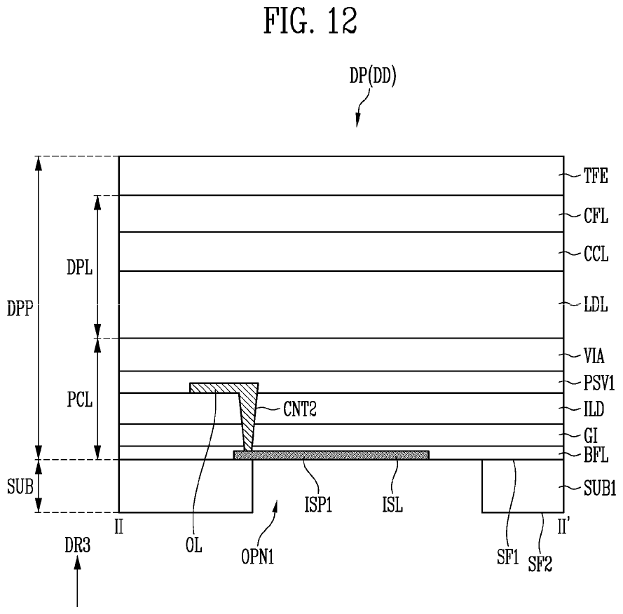

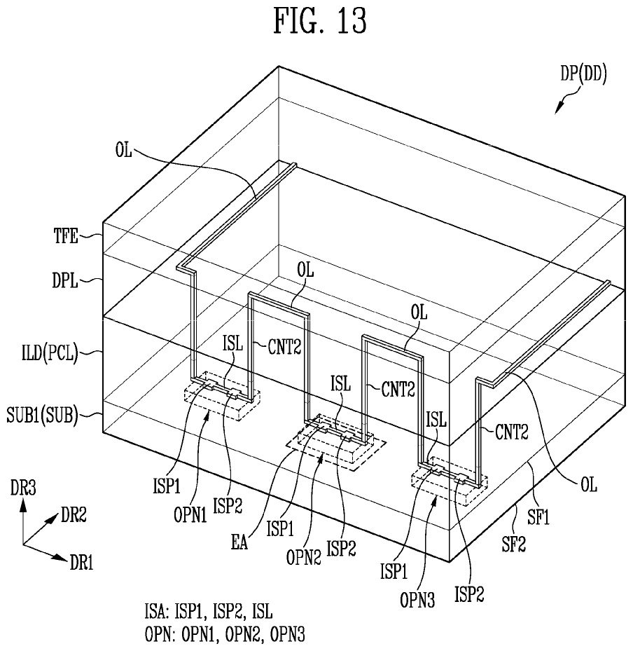

FIG. 8 is a schematic perspective view illustrating the display device DD according to an embodiment. FIG. 9 is a schematic bottom view illustrating the display device DD of FIG. 8. FIG. 10 is a schematic enlarged view illustrating a portion EA of FIG. 8. FIGS. 11 and 12 are schematic cross-sectional views taken along line II-II′ of FIG. 8. FIG. 13 is a schematic perspective view illustrating a state in which a dummy area DMA is removed from the display device DD of FIG. 8.

In FIGS. 8 to 13, the display device DD may be one of a plurality of display devices (or display panels) separated from a mother substrate as cells.

In order to avoid overlapping descriptions with respect to the embodiments of FIGS. 8 to 13, differences from the above-described embodiments will be mainly described.

Referring to FIGS. 1 to 13, the display device DD (or display panel DP) according to an embodiment may include a first area A1 and a second area A2 partitioned by a cutting line CL. The first area A1 may be an area where the display part DPP is located in a final product after a manufacturing process of the display device DD is completed, but the disclosure is not limited thereto. The second area A2 may be the dummy area DMA where a first dummy pad INP and a second dummy pad OUP are exposed, and may be removed by a laser scribing process or the like after an inspection process.

The display device DD may include the substrate SUB, the pixel circuit layer PCL, the display element layer DPL, and the thin film encapsulation layer TFE.

The substrate SUB may include the first substrate SUB1 including the first surface SF1 and the second surface SF2 facing each other in the third direction DR3, the barrier layer BR and the second substrate SUB2 sequentially disposed on the first substrate SUB1.

In an embodiment, the first substrate SUB1 may include the openings OPN penetrating the first and second surfaces SF1 and SF2. The openings OPN may include first, second, and third openings OPN1, OPN2, and OPN3 spaced apart from each other. The first, second, and third openings OPN1, OPN2, and OPN3 may correspond to positions where the second pad PD2 electrically connected to the driver DIC positioned below the first substrate SUB1 is formed, but the disclosure is not limited thereto.

The inspection array ISA may be disposed and/or formed on the first surface SF1 of the first substrate SUB1.

The inspection array ISA may be disposed on the first surface SF1 of the first substrate SUB1 and may be covered by the barrier layer BR. In the process of forming the openings OPN, the inspection array ISA may be exposed to the outside on the second surface SF2 of the first substrate SUB1 by a corresponding opening OPN. In an embodiment, the inspection array ISA may be disposed on the first surface SF1 of the first substrate SUB1 to correspond to positions where the openings OPN are formed.

According to an embodiment, as shown in FIG. 12, in the display device DD in which the barrier layer BR and the second substrate SUB2 are omitted, the buffer layer BFL may be disposed on the first substrate SUB1. Hence, the inspection array ISA may be covered by the buffer layer BFL, but the disclosure is not limited thereto.

The inspection array ISA may include an inspection line ISL and first and second inspection pads ISP1 and ISP2. The inspection line ISL and the first and second inspection pads ISP1 and ISP2 may be formed in the same process and may be disposed on a same layer. For example, the inspection line ISL and the first and second inspection pads ISP1 and ISP2 may be integral with each other and electrically connected to each other. Each of the first and second inspection pads ISP1 and ISP2 may have a wider width than the inspection line ISL, but the disclosure is not limited thereto.

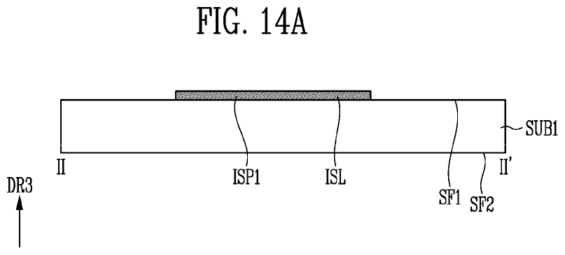

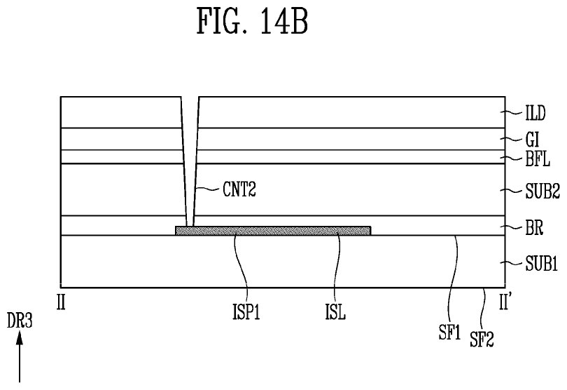

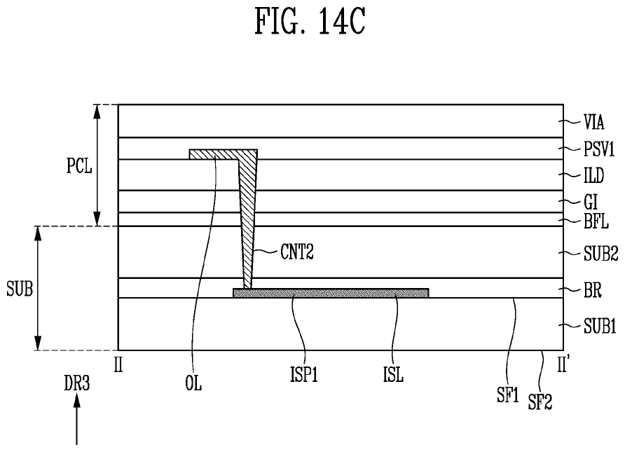

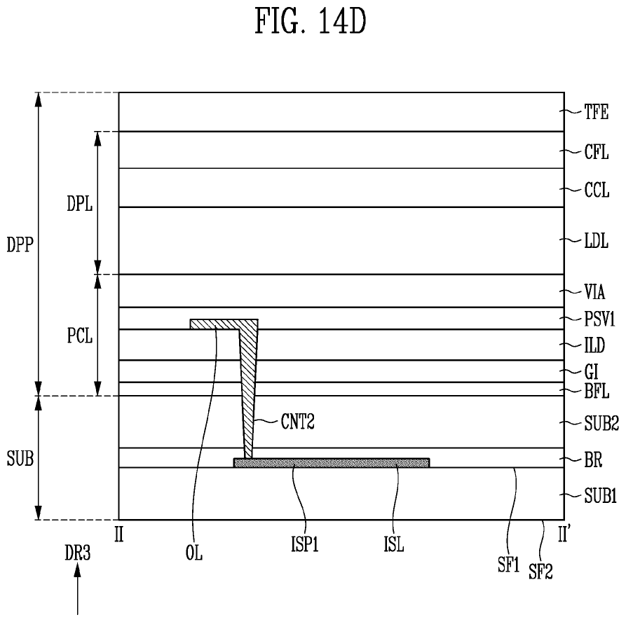

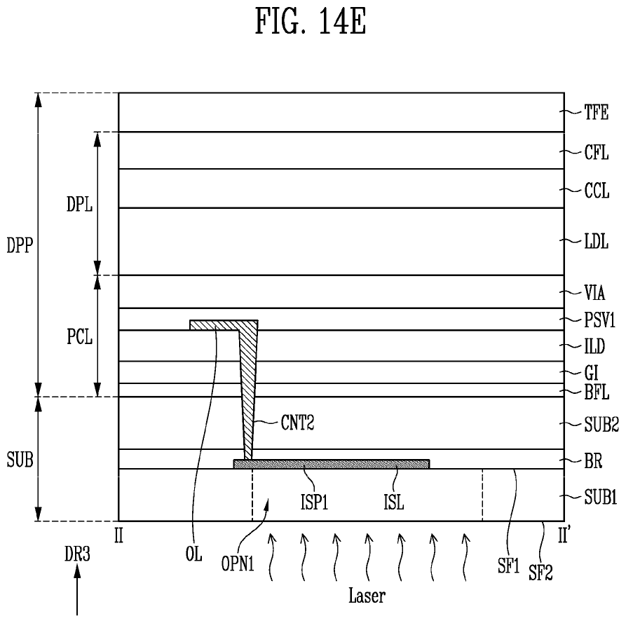

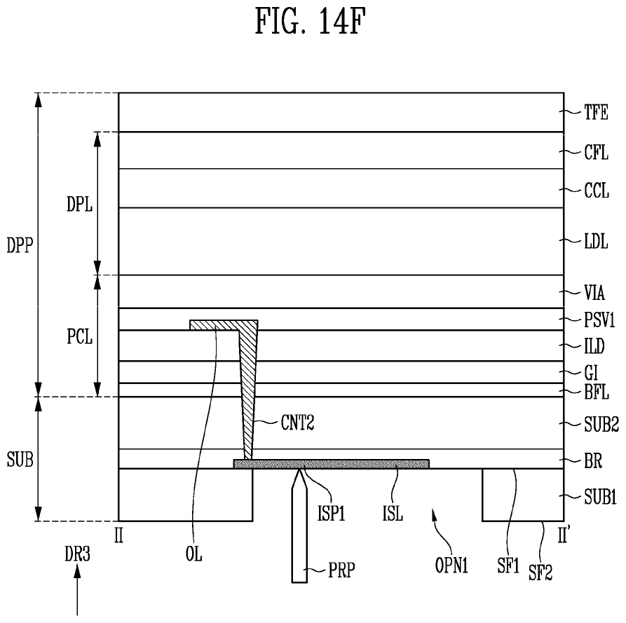

The first and second inspection pads ISP1 and ISP2 may be inspection pads for performing an OS (open short) inspection performed after the openings OPN are formed in the first substrate SUB1. For example, the OS inspection may be an inspection for detecting a defect (for example, an open or short circuit in a line) in the inspection line ISL exposed by the openings OPN. The etching degree of the first substrate SUB1 in the openings OPN may be confirmed through the OS inspection. In the process of confirming the etching degree of the first substrate SUB1, the first and second inspection pads ISP1 and ISP2 may electrically contact external probe pins PRP (refer to FIG. 14F).

The first inspection pad ISP1 may be electrically connected to a first side of the inspection line ISL, and the second inspection pad ISP2 may be electrically connected to a second side of the inspection line ISL. The inspection line ISL may be a shape bent at least once between the first inspection pad ISP1 and the second inspection pad ISP2. For example, the inspection line ISL may be implemented in a zigzag shape between the first inspection pad ISP1 and the second inspection pad ISP2, but the disclosure is not limited thereto.

The inspection array ISA may be disposed on a same layer as the first pad PD1 and may be disposed to be spaced apart from the first pad PD1. In an embodiment, the inspection array ISA and the first pad PD1 may be electrically insulated.

The barrier layer BR and the second substrate SUB2 may be sequentially disposed on the first substrate SUB1 on which the inspection array ISA is disposed.

The pixel circuit layer PCL may be disposed on the substrate SUB described above.

The pixel circuit layer PCL may include an outer line OL disposed on the interlayer insulating layer ILD.

The outer line OL may be disposed to be spaced apart from the circuit elements (for example, the transistor T) and the signal lines electrically connected to the transistor T in the pixel circuit layer PCL, and may be electrically insulated from the circuit elements and the signal lines. The outer line OL may be located in the display area DA or the non-display area NDA of the display device DD according to embodiments. The outer line OL may have a shape extending from a first side of the first dummy pad INP (or second dummy pad OUP) to a first side of the second dummy pad OUP (or first dummy pad INP) along an edge of the first area A1 of the display device DD, but the disclosure is not limited thereto. For example, a first end of the outer line OL may extend from a first side of the first dummy pad INP, and a second end of the outer line OL may extend from a first side of the second dummy pad OUP.

The outer line OL may be integral with the first and second dummy pads INP and OUP and electrically connected to each other. The outer line OL and the first and second dummy pads INP and OUP may be formed in the same process and may be disposed on a same layer. For example, the outer line OL and the first and second dummy pads INP and OUP may be integral with each other on the interlayer insulating layer ILD and electrically connected to each other. The outer line OL and the first and second dummy pads INP and OUP may be disposed and/or formed on a same layer as the first and second connection members CNE1 and CNE2 of the pixel circuit layer PCL. Each of the first and second dummy pads INP and OUP may have a wider width than the outer line OL, but the disclosure is not limited thereto.

The outer line OL may be electrically connected to the inspection array ISA through a second contact hole CNT2 penetrating one or more components of the pixel circuit layer PCL and one or more components of the substrate SUB. For example, as shown in FIG. 11, the outer line OL may be electrically connected to the inspection array ISA through the second contact hole CNT2 sequentially penetrating the interlayer insulating layer ILD, the gate insulating layer GI, the buffer layer BFL, the second substrate SUB2, and the barrier layer BR. In the above-described embodiment, a case where the outer line OL is disposed on the interlayer insulating layer ILD has been described, but the disclosure is not limited thereto. According to an embodiment, the outer line OL may be disposed on one insulating layer among insulating layers included in the pixel circuit layer PCL or may be disposed on the second substrate SUB2. In case that the outer line OL is disposed on the second substrate SUB2, the outer line OL may be formed in the same process as the lower metal pattern BML and may be disposed on a same layer.

The first and second dummy pads INP and OUP may be disposed on the interlayer insulating layer ILD of the pixel circuit layer PCL in the dummy area DMA, and may be exposed to the outside without being covered by the display element layer DPL and the thin film encapsulation layer TFE. The first and second dummy pads INP and OUP may be components constructed and arranged to confirm an electrical connection between the outer line OL and the inspection array ISA by applying a selectable signal after forming the openings OPN. In an embodiment, the first and second dummy pads INP and OUP may be constructed and arranged to confirm a current value or a voltage value by applying a selectable signal (for example, an inspection signal) to the outer line OL in order to confirm whether the inspection array ISA (or the inspection line ISL) is defective in the openings OPN after forming the openings OPN in the first substrate SUB1.

In the OS inspection performed after forming the openings OPN penetrating the first and second surfaces SF1 and SF2 of the first substrate SUB1, a selectable signal may be applied to the outer line OL through an input pad (for example, the first dummy pad INP) among the dummy pads INP and OUP, and it may be determined whether the inspection array ISA is defective by measuring the electrical current value or voltage value of an electrical signal passing through the inspection array ISA electrically connected to the outer line OL through the second contact hole CNT2 at an output pad among the dummy pads INP and OUP. In case that the first substrate SUB1 is over-etched in the process of forming the openings OPN, a value (e.g., a predetermined or measurable value) may not be measured due to a defect in the inspection array ISA. Through this, the etching degree of the first substrate SUB1 can be easily confirmed in the process of forming the openings OPN, and manufacturing efficiency of the display device DD can be improved.

It may be determined whether the first substrate SUB1 exists between the first and second inspection pads ISP1 and ISP2 and the probe pins PRP by contacting the probe pins PRP to the first and second inspection pads ISP1 and ISP2 of the inspection array ISA exposed through the openings OPN of the first substrate SUB1. In case that the first substrate SUB1 exists between the first and second inspection pads ISP1 and ISP2 and the probe pins PRP, since the probe pins PRP does not contact the first and second inspection pads ISP1 and ISP2, no signal may be measured. Through this, it may be determined whether a defect has occurred in the manufacturing process of the display device DD by confirming whether the openings OPN are properly formed in the first substrate SUB1.

In the OS inspection process described above, in case that a measurable value is measured at the output pad among the first and second dummy pads INP and OUP, it may be determined that the first substrate SUB1 is etched to a desired level (or normally) in the process of forming the openings OPN, and a process of removing the dummy area DMA from the display device DD may be additionally performed as shown in FIG. 13 by performing a scribing process using a laser or the like. Once the dummy area DMA is removed, the outer line OL may not be electrically connected to other lines except for the inspection array ISA.

A process of processing an edge of the display device DD may be performed after the process of removing the dummy area DMA.

According to the above-described embodiments, the inspection array ISA may be formed on the first surface SF1 of the first substrate SUB1 and exposed on the second surface SF2, and the outer line OL may be formed on a layer, for example, the interlayer insulating layer ILD, disposed on the first surface SF1. Electrically connecting the inspection array ISA and the outer line OL and applying a selectable signal through the first and second dummy pads INP and OUP electrically connected to the outer line OL, enables the etching degree of the first substrate SUB1 to be readily determined within the process of forming the openings OPN penetrating the first surface SF1 and the second surface SF2.

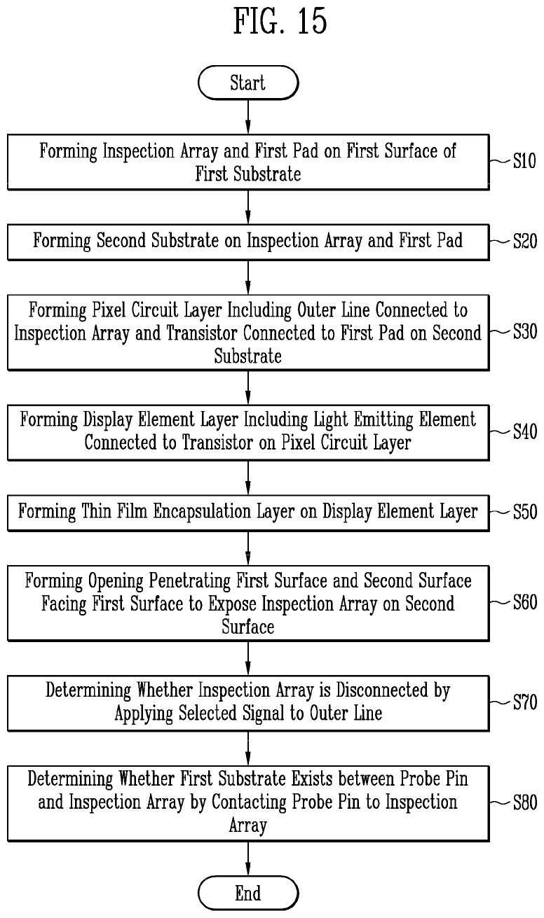

FIGS. 14A to 14F are schematic cross-sectional views illustrating a manufacturing sequence of a display device according to an embodiment, and are schematic cross-sectional views taken along line II-II′ of FIG. 8. FIG. 15 is a schematic flowchart illustrating a method of manufacturing a display device according to an embodiment.

Hereinafter, a method of manufacturing a display device according to an embodiment will be described with reference to FIGS. 14A to 15.

Steps for manufacturing the display device may be described as being sequentially performed along the schematic cross-sectional views. However, as long as the technical scope of the disclosure is not changed, one or more steps that are performed sequentially may be performed simultaneously, the order of steps may be changed, one or more steps may be omitted, or other steps may be further included between the steps.

In FIGS. 14A to 15, in order to avoid overlapping descriptions, differences from the above-described embodiments will be described.

Referring to FIGS. 6 to 8, 14A, and 15, a first substrate SUB1 including a first surface SF1 (or upper surface) and a second surface SF2 (or lower surface) facing each other in a third direction DR3 (or thickness direction) may be prepared. The first substrate SUB1 may include polyimide.

An inspection array ISA including an inspection line ISL and first and second inspection pads ISP1 and ISP2 may be formed on the first surface SF1 of the first substrate SUB1. A first pad PD1 may be formed on the first surface SF1 of the first substrate SUB1. (S10)

The first and second inspection pads ISP1 and ISP2 and the inspection line ISL may be integral with each other and electrically connected to each other. The inspection array ISA and the first pad PD1 may be electrically insulated (or separated).

Referring to FIGS. 6 to 8, 14A, 14B, and 15, a barrier layer BR and a second substrate SUB2 may be sequentially formed on the inspection array ISA and the first pad PD1. (S20)

The barrier layer BR may be an inorganic insulating layer including an inorganic material, and may be composed of a single layer or multiple layers including a double layer. The second substrate SUB2 may include polyimide.

A buffer layer BFL, a gate insulating layer GI, and an interlayer insulating layer ILD may be formed on the second substrate SUB2. Subsequently, a portion of the inspection array ISA may be exposed by forming a second contact hole CNT2 sequentially penetrating the interlayer insulating layer ILD, the gate insulating layer GI, the buffer layer BFL, the second substrate SUB2, and the barrier layer BR.

In the above process, a first contact hole CNT1 sequentially penetrating the interlayer insulating layer ILD, the gate insulating layer GI, the buffer layer BFL, the second substrate SUB2, and the barrier layer BR may be formed, and a portion of the first pad PD1 may be exposed.

Also, in the above process, a lower metal pattern BML, a transistor T, and signal lines electrically connected to the transistor T may be formed in an emission area EMA.

Referring to FIGS. 6 to 8, 14A to 14C, and 15, an outer line OL and first and second dummy pads INP and OUP may be formed on the interlayer insulating layer ILD. The outer line OL and the first and second dummy pads INP and OUP may be integral with each other and electrically connected to each other. The outer line OL may be electrically connected to the inspection array ISA through the second contact hole CNT2. For example, the outer line OL may be electrically connected to the inspection line ISL of the inspection array ISA through the contact hole CNT2.

In the above process, first and second connection members CNE1 and CNE2 may be formed on the interlayer insulating layer ILD of the emission area EMA.

A pixel circuit layer PCL may be formed on the second substrate SUB2 (or substrate SUB) by sequentially forming a first passivation layer PSV1 and a via layer VIA on the outer line OL, the first and second dummy pads INP and OUP, and the first and second connection members CNE1 and CNE2. (S30)

The first passivation layer PSV1 and the via layer VIA may be partially opened to expose the first and second dummy pads INP and OUP.

Referring to FIGS. 6 to 8, 14A to 14D, and 15, a display element layer DPL may be formed on the pixel circuit layer PCL. (S40)

The display element layer DPL may include a light emitting element layer LDL, a color conversion layer CCL, a color filter layer CFL, or a combination thereof.

A thin film encapsulation layer TFE may be formed on the display element layer DPL. (S50)

The first and second dummy pads INP and OUP included in the pixel circuit layer PCL may be exposed to outside without being covered by the display element layer DPL and the thin film encapsulation layer TFE.

Subsequently, the display device DD may be separated from a mother substrate in units of cells by a scribing process using a laser or the like.

Referring to FIGS. 6 to 8, 14A to 14E, and 15, the inspection array ISA and the first pad PD1 may be exposed on the second surface SF2 by forming an opening OPN and a through hole TH penetrating the first surface SF1 and the second surface SF2 of the first substrate SUB1. (S60)

For example, the opening OPN and the through hole TH may be formed by at least one of a dry etching process, a plasma etching process, and a laser etching process, but the disclosure is not limited thereto. In an embodiment, the opening OPN and the through hole TH may be formed by a laser etching process.

Referring to FIGS. 6 to 8 and 15, an electrical connection between the outer line OL and the inspection array ISA may be inspected based on applying a selectable signal to the first and second dummy pads INP and OUP. Hence, it may be determined whether the inspection array ISA is defective (for example, disconnection or the like) based on applying a selectable signal to the outer line OL and the inspection array ISA through the first and second dummy pads INP and OUP. Hence, a disconnection defect of the inspection array ISA electrically connected to the outer line OL may be confirmed by applying the selectable signal to the first and second dummy pads INP and OUP. (S70)

Referring to FIGS. 6 to 8, 14A to 14F, and 15, it may be determined whether the first substrate SUB1 exists between the inspection array ISA and probe pins PRP based on contacting the probe pins PRP to the first and second inspection pads ISP1 and ISP2 of the inspection array ISA, respectively, within the opening OPN of the first substrate SUB1. (S80)

According to the embodiments, an inspection line and an inspection pad integral with the inspection line may be formed on a first surface of a substrate, and an outer line electrically connected to the inspection line through a contact hole and a dummy pad integral with the outer line may be formed. Thereafter, an opening penetrating first and second surfaces of the substrate may be formed, and the inspection line and the inspection pad may be exposed to outside through the opening. By applying a selectable signal to the dummy pad to confirm an electrical connection between the outer line and the inspection line, the etching degree of the substrate can be determined in the process of forming the opening and a defect in a display device including the substrate can be easily determined. Accordingly, manufacturing efficiency of the display device can be improved.

According to the embodiments, by contacting probe pins to the inspection pad and confirming whether the substrate exists between the inspection pad and the probe pins, it may be easily determined whether the opening is properly formed to meet a measurable condition. Accordingly, manufacturing efficiency of the display device can be further improved.

Effects according to the embodiments are not limited by the contents exemplified above, and more various effects are included in this specification.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a first substrate including first and second surfaces facing each other, and including at least one opening penetrating the first and second surfaces;
an inspection array disposed on the first surface and exposed on the second surface by the opening;
a pixel circuit layer disposed on the first surface and including at least one transistor and an outer line; and
a display element layer disposed on the pixel circuit layer and including a light emitting element electrically connected to the transistor,
wherein the inspection array is electrically connected to the outer line.

2. The display device of claim 1, wherein
the outer line is disposed on the inspection array with an insulating layer disposed between the outer line and the inspection array, and
the outer line is electrically connected to the inspection array through a contact hole penetrating the insulating layer.

3. The display device of claim 2, wherein
the inspection array includes an inspection pad and an inspection line integral with the inspection pad, and
the inspection array is disposed on the first surface at a position corresponding to the opening.

4. The display device of claim 3, wherein
the outer line extends on the insulating layer, and
the outer line is electrically connected to the inspection line through the contact hole.

5. The display device of claim 4, wherein
the inspection pad includes:
a first inspection pad electrically connected to a first side of the inspection line; and
a second inspection pad electrically connected to a second side of the inspection line, and
the inspection line has a shape that is bent at least once between the first inspection pad and the second inspection pad.

6. The display device of claim 4, wherein the outer line is not connected to another line except for the inspection array.

7. The display device of claim 4, further comprising:
a first pad disposed on the first surface and exposed on the second surface through a through hole penetrating the first surface and the second surface,
wherein the first pad is electrically insulated from the inspection array.

8. The display device of claim 7, wherein the first pad and the inspection array are disposed on a same layer.

9. The display device of claim 7, further comprising:
a barrier layer disposed on the first substrate and covering the inspection array;
a second substrate disposed between the barrier layer and the pixel circuit layer; and
a thin film encapsulation layer disposed on the display element layer.

10. The display device of claim 9, further comprising:
a second pad disposed in the through hole and electrically connected to the first pad;
a flexible circuit film electrically connected to a lower surface of the second pad; and
a driver disposed on the flexible circuit film and constructed and arranged to supply a signal to the first pad.

11. The display device of claim 1, wherein the display element layer further includes:
a light emitting element layer disposed on the pixel circuit layer and including the light emitting element;
a color conversion layer disposed on the light emitting element layer and constructed and arranged to convert and output light emitted from the light emitting element; and
a color filter layer disposed on the color conversion layer and constructed and arranged to selectively transmit the light converted by the color conversion layer.

12. The display device of claim 1, wherein the first substrate includes polyimide.

13. A method of manufacturing a display device comprising:
forming an inspection array on a first surface of a first substrate;
forming a barrier layer covering the inspection array and forming a second substrate on the barrier layer;
forming a pixel circuit layer including an outer line electrically connected to the inspection array and a dummy pad integral with the outer line on the second substrate;
forming a display element layer including a light emitting element on the pixel circuit layer;
forming a thin film encapsulation film on the display element layer;
forming at least one opening penetrating the first surface and a second surface facing the first surface; and
inspecting an electrical connection between the outer line and the inspection array by applying a selectable signal to the dummy pad.

14. The method of claim 13, wherein
the inspection array includes an inspection pad and an inspection line integral with the inspection pad, and
the inspection array is formed on the first surface at a position corresponding to the opening.

15. The method of claim 14, wherein the forming the pixel circuit layer includes:
forming at least one insulating layer on the second substrate;
forming a contact hole sequentially penetrating the insulating layer, the second substrate, and the barrier layer and that exposes a portion of the inspection line; and
forming the outer line electrically connected to the inspection line through the contact hole.

16. The method of claim 15, wherein
the dummy pad includes a first dummy pad electrically connected to a first side of the outer line and a second dummy pad spaced apart from the first dummy pad and electrically connected to a second side of the outer line; and
the inspecting the electrical connection comprises confirming a disconnection defect in the electrical connection of the inspection array based on applying the selectable signal to the first and second dummy pads.

17. The method of claim 16, wherein the inspecting the electrical connection includes:
confirming whether the first substrate exists between a probe pin and the inspection pad based on contacting the probe pin to the inspection pad of the inspection array.

18. The method of claim 13, wherein the forming the inspection array includes:
forming a first pad electrically insulated from the inspection array on the first surface.

19. The method of claim 13, further comprising:
removing the dummy pad from the first substrate after the inspecting the electrical connection.

20. The method of claim 19, wherein the outer line is not connected to other lines except for the inspection array.
